(19) United States
(12) Patent Application Publication
(10) Pub. No.: US 2026/0239667 A1
(43) Pub. Date: Aug. 13, 2026

(54) INSULATED GATE SEMICONDUCTOR DEVICE

(71) Applicant: FUJI ELECTRIC CO., LTD., Kawasaki-shi (JP)

(72) Inventor: Yasuyuki HOSHI, Matsumoto-city (JP)

(73) Assignee: FUJI ELECTRIC CO., LTD., Kawasaki-shi (JP)

(21) Appl. No.: 19/439,112

(22) Filed: Jan. 2, 2026

(30) Foreign Application Priority Data
Feb. 13, 2025 (JP) 2025-021785

(51) Int. Cl. H10D 30/66; H10D 62/10; H10D 62/60; H10D 62/832; H10D 64/27; H10D 12/00

(52) U.S. Cl. CPC H10D 30/668; H10D 62/103; H10D 62/126; H10D 62/60; H10D 62/8325; H10D 64/518; H10D 12/481

(57) ABSTRACT

The insulated gate semiconductor device includes: a drift layer; a current spreading layer provided on a top surface side of the drift layer; a base region provided on a top surface side of the current spreading layer; a main electrode region provided on a top surface side of the base region; a plurality of trenches extending through the main electrode region and the base region and arranged at a first interval in a plan view; and a gate electrode buried in each of the plurality of trenches via a gate insulating film and configured to form an inversion layer in a region of the base region which region is separated from an interface between the base region and the each of the plurality of trenches in response to voltage application. The current spreading layer includes a top-side portion located between two adjacent trenches among the plurality of trenches.

### CROSS-REFERENCE TO RELATED APPLICATION

This application claims benefit of priority under 35 USC 119 based on Japanese Patent Application No. 2025-021785 filed on February 13, 2025, the entire contents of which are incorporated by reference herein.

### BACKGROUND OF THE INVENTION

### Field of the Invention

This disclosure relates to an insulated gate semiconductor device.

### Description of the Related Art

JP 6631632 B2 (Patent Literature 1) and F.Udrea et al., "Experimental demonstration, challenges, and prospects of the vertical SiC FinFET", 2022 IEEE 34th ISPSD, May 2022 (Non Patent Literature 1) describe a vertical SiC-MOSFET having a trench gate structure incorporating unit cells (functional units of a device) configured with a FinFET structure (Metal Oxide Semiconductor Field Effect Transistor: a MOS field effect transistor including an insulated gate and having a three layer structure of Metal-Oxide Film-Semiconductor).

However, in Patent Literature 1 and Non Patent Literature 1, the Fin width (the width between gate trenches adjacent to each other) is narrow. Because of this, the transport path of carriers is narrowed. In addition, carriers may be affected by JFET resistance.

### SUMMARY OF THE INVENTION

This disclosure is accomplished in view of the above problems, and an object of the present invention is to provide an insulated gate semiconductor device in which conduction resistance is reduced.

In order to achieve the above object, an insulated gate semiconductor device according to one aspect of this disclosure includes: a drift layer of a first conductivity type; a current spreading layer of the first conductivity type, provided on a top surface side of the drift layer and having a higher impurity concentration than the drift layer; a base region of a second conductivity type, provided on a top surface side of the current spreading layer; a main electrode region of the first conductivity type, provided on a top surface side of the base region; a plurality of trenches extending through the main electrode region and the base region and arranged at a first interval in a plan view; and a gate electrode buried in each of the plurality of trenches via a gate insulating film and configured to form an inversion layer in a region of the base region which region is separated from an interface between the base region and the each of the plurality of trenches in response to voltage application. The current spreading layer includes a top-side portion located between two adjacent trenches among the plurality of trenches.

The insulated gate semiconductor device may further include a gate bottom protection region of the second conductivity type, provided in the current spreading layer and in contact with a bottom surface of the trench for each of the plurality of trenches.

Each of the plurality of trenches may have a depth dimension of 0.3 μm or more and 0.6 μm or less.

The insulated gate semiconductor device may further include a gate bottom protection region of the second conductivity type, provided in the current spreading layer and in contact with a bottom surface of the trench for each of the plurality of trenches, and the gate bottom protection region may have a depth dimension of 0.1 μm or more and 0.2 μm or less.

The gate bottom protection region may have a bottom surface separated from a bottom surface of the current spreading layer by 0.1 μm or more and 0.2 μm or less.

Each of the plurality of trenches may include a lower corner having a curved surface with a curvature radius of 0.1 μm or more and 0.25 μm or less.

Each of the plurality of trenches may include a lower corner having a curved surface with a curvature radius of 0.1 μm or more and 0.25 μm or less. The insulated gate semiconductor device may further include a gate bottom protection region of the second conductivity type, provided in the current spreading layer and in contact with a bottom surface of the trench for each of the plurality of trenches. One end portion and the other end portion of the gate bottom protection region in an arrangement direction the plurality of trenches may be located nearer to a center of the trench than a pair of side walls of the trench.

The first interval may be 0.3 μm or less.

The drift layer, the base region, and the main electrode region may be made of silicon carbide or silicon.

Note that the summary of the disclosure does not describe all necessary features of this disclosure. Subcombinations of these features can also be included in the disclosure.

### BRIEF DESCRIPTION OF THE DRAWINGS

FIG. 1 is a view to describe the positional relationship in a plan view between a gate electrode, a source region, and a base contact region included in an insulated gate semiconductor device according to a first embodiment;

FIG. 2 is a longitudinal sectional view illustrating a sectional configuration taken along a line A-A in FIG. 1;

FIG. 3 is a longitudinal sectional view illustrating part of one unit cell in FIG. 2 in an enlarged manner;

FIG. 4 is a longitudinal sectional view illustrating part of one unit cell according to a second embodiment in an enlarged manner;

FIG. 5 is a longitudinal sectional view illustrating part of one unit cell according to a third embodiment in an enlarged manner; and

FIG. 6 is a view illustrating simulation results of drain current density for the insulated gate semiconductor devices according to the first to third embodiments and an insulated gate semiconductor device according to a comparative example.

### DETAILED DESCRIPTION

With reference to the drawings, the following describes a first to third embodiments of this disclosure. In the description for the drawings, identical or similar constituents have identical or similar reference signs, and redundant descriptions are omitted. Note that, the drawings are schematic, and the relationship between thickness and flat dimension, the ratio between layer thicknesses, and the like may be different from actual ones. In addition, the drawings may include portions having different dimensional relationships or ratios. Further, the first to third embodiments described below exemplify devices or methods to embody the technical idea of this disclosure, and the technical idea of this disclosure does not limit the materials, shapes, structures, arrangements and the like of a constituent component to those described below.

In the present specification, the source region of a field effect transistor (FET) is "one main electrode region (a first main electrode region)" selectable as the emitter region of an insulated gate bipolar transistor (IGBT). In a thyristor such as an MOS controlled static induction thyristor (SI thyristor), the "one main electrode region" is selectable as the cathode region. The drain region of the FET is "the other main electrode region (a second main electrode region)" of a semiconductor device that is selectable as the collector region in the IGBT or the anode region in the thyristor. When the "main electrode region" is just referred to in the present specification, the "main electrode region" indicates the appropriate one of the first main electrode region and the second main electrode region based on a common general technical knowledge of those skilled in the art.

Further, the definitions of directions such as "up" and "down" in the following description are merely definitions for convenience of the description and do not restrict the technical idea of this disclosure. For example, when a target is rotated by 90° and observed, the "up-down direction" is replaced with the "right-left direction," and when the target is rotated by 180° and observed, the top and bottom are upside down. Also, "top surface" may be read as "front surface," and "bottom surface" may be read as "back surface."

The following description illustratively describes a case where a first conductivity type is n-type, and a second conductivity type is p-type. However, the conductivity types may be reversed such that the first conductivity type is p-type, and the second conductivity type is n-type. Sign "+" to be added to "n" or "p" indicates a semiconductor region having a relatively high impurity concentration in comparison with a semiconductor region without "+," and sign "-" to be added to "n" or "p" indicates a semiconductor region having a relatively low impurity concentration in comparison with a semiconductor region without "-." Note that separate semiconductor regions assigned with "n" may have different impurity concentrations.

### FIRST EMBODIMENT

### Structure of Insulated Gate Semiconductor Device

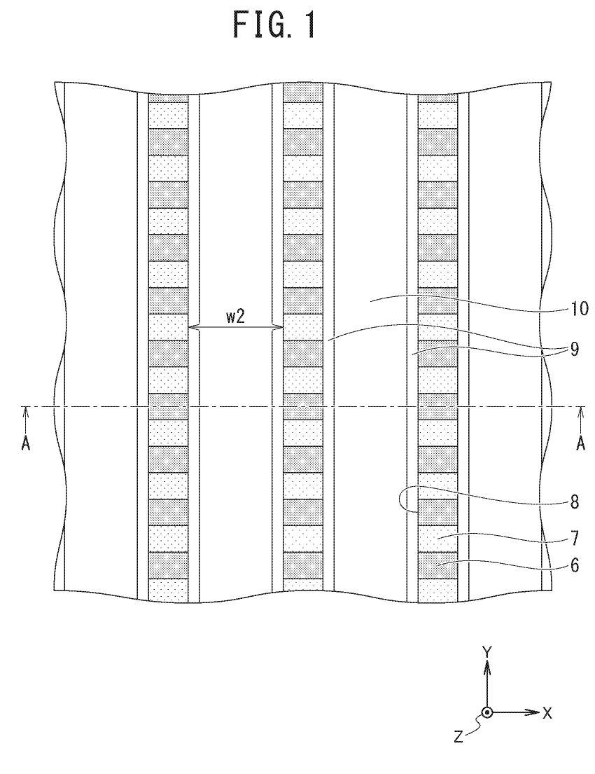

FIGS. 1 to 3 are views illustrating exemplary configurations of an insulated gate semiconductor device (MISFET) according to a first embodiment of this disclosure. The insulated gate semiconductor device according to the first embodiment is a power device and includes a trench gate FET as an active element. The insulated gate semiconductor device according to the first embodiment includes a semiconductor layer, which may be made of silicon carbide (SiC), for example, or may be made of silicon (Si), for example. That the semiconductor layer of the insulated gate semiconductor device

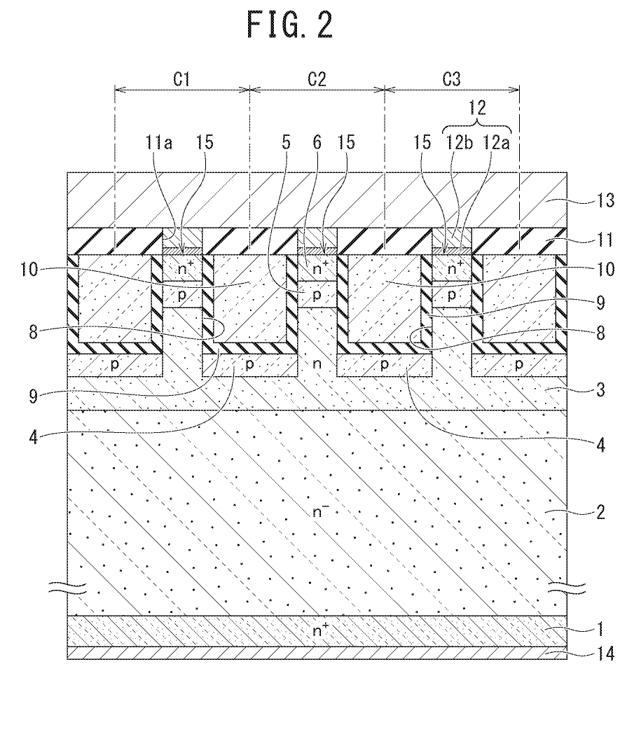

is made of SiC or Si may include a case where the semiconductor layer mainly contains SiC or Si. The present embodiment deals with a case where the semiconductor layer of the insulated gate semiconductor device is made of SiC. The present embodiment also deals with a case where the technology of this disclosure is applied to a unit cell configured with a FinFET structure. FIG. 2 illustrates unit cells (functional units of the device) C1, C2, C3 with the FinFET structure. The unit cells C1, C2, C3 with the FinFET structure each includes a Fin section 15. The number of unit cells is not limited to FIG. 2, and a plurality of unit cells is arranged periodically.

The insulated gate semiconductor device according to the first embodiment includes a drift layer 2 of the first conductivity type (n⁻-type). The drift layer 2 is constituted by an epitaxially-grown layer made of SiC, for example. The drift layer 2 has an impurity concentration of approximately about 1 × 10¹⁵ cm⁻³ or more and 5 × 10¹⁶ cm⁻³ or less, for example. The impurity concentration and thickness of the drift layer 2 can be adjusted appropriately according to the breakdown voltage rating and other design specifications.

A current spreading layer (CSL) 3 of the first conductivity type (n-type) with a higher impurity concentration than that of the drift layer 2 is selectively provided on the top surface side of the drift layer 2. The bottom surface of the current spreading layer 3 is in contact with the top surface of the drift layer 2. The current spreading layer 3 is constituted by an epitaxially-grown layer made of SiC, for example. The current spreading layer 3 has an impurity concentration of approximately 5 × 10¹⁶ cm⁻³ or more and 5 × 10¹⁷ cm⁻³ or less, for example.

A base region 5 of the second conductivity type (p-type) is provided on the top surface side of the current spreading layer 3. The bottom surface of the base region 5 is in contact with the top surface of the current spreading layer 3. The bottom surface of the base region 5 is in direct contact with the top surface of the current spreading layer 3. The base region 5 is constituted by an epitaxially-grown layer made of SiC, for example. The base region 5 may be a region where p-type impurities are ion-implanted into the current spreading layer 3. The base region 5 has an impurity concentration of approximately 1 × 10¹⁷ cm⁻³ or more and 1 × 10¹⁸ cm⁻³ or less, for example.

A First main electrode region (source region) 6 of the first conductivity type (n⁺-type) with a higher impurity concentration than that of the drift layer 2 is selectively provided on the top surface side of the base region 5. The source region 6 is a region made of SiC formed by performing ion implantation of n-type impurities on the base region 5, for example. The bottom surface of the source region 6 is in contact with the top surface of the base region 5. The source region 6 has an impurity concentration of approximately 1 × 10¹⁷ cm⁻³ or more and 5 × 10¹⁸ cm⁻³ or less, for example.

Although not illustrated in FIG. 2, a base contact region 7 of the second conductivity type (p⁺-type) with a higher impurity concentration than that of the base region 5 is selectively provided on the top surface side of the base region 5. The base contact region 7 is a region made of SiC formed by performing ion implantation of p-type impurities on the base region 5, for example. The bottom surface of the base contact region 7 is in contact with the top surface of the base region 5. The base contact region 7 has an impurity concentration of approximately 5 × 10¹⁹ cm⁻³ or more and 5 × 10²⁰ cm⁻³ or less, for example.

As illustrated in FIG. 1, the base contact region 7 is provided adjacent to the source region 6 along the Y-direction. More specifically, the base contact region 7 and the source region 6 are provided alternately along the Y-direction. The source region 6 and the base contact region 7 may not be in contact with each other.

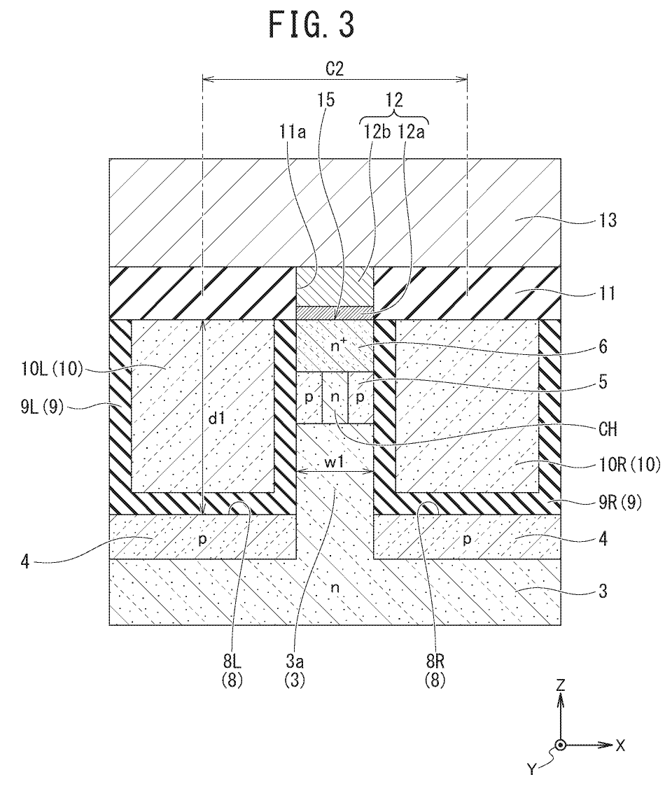

A plurality of trenches 8 extending through the base contact region 7, the source region 6, and the base region 5 is provided from the top surfaces of the base contact region 7 and the source region 6 toward the normal direction (the depth direction, the Z-direction) of the top surfaces of the base contact region 7 and the source region 6. The trenches 8 form a stripe plane pattern. For example, the trenches 8 are elongated along the Y-direction in a plan view and are arranged at an interval (a first interval) along the X-direction. The trenches 8 each have a width w2 in their arrangement direction (their short direction), and the width w2 is approximately 0.3 μm or more and 1.0 μm or less, for example. As illustrated in FIG. 2, the right and left lateral surfaces of the trench 8 are in contact with the source region 6, the base region 5, and the current spreading layer 3, and the bottom surface of the trench 8 reaches the current spreading layer 3. The trench 8 has a depth dimension d1 of approximately 1 μm, for example. The semiconductor region located between the trenches 8 adjacent to each other serves as the Fin section 15. The Fin section 15 may have a stripe shape elongated in the rearward direction and the forward direction relative to the surface of paper of FIG. 2, for example. The base contact region 7, the source region 6, the base region 5, and the current spreading layer 3 are provided between the trenches 8 adjacent to each other. As illustrated in FIG. 3, a top-side portion of the current spreading layer 3 is located between the trenches 8 adjacent to each other. The top-side portion of the current spreading layer 3, located between the trenches 8 adjacent to each other, is referred to as a current spreading layer 3a and distinguished from other portions of the current spreading layer 3. Note that, in a case where the current spreading layer 3a is not distinguished from other portions of the current spreading layer 3, it is just referred to as the current spreading layer 3. Note that the trenches 8 may form a dotted plane pattern, instead of the stripe plane pattern.

As illustrated in FIG. 2, a gate insulating film 9 is provided on the inner surface of the trench 8, more specifically, along the bottom surface and the opposite lateral surfaces of the trench 8. A gate electrode 10 is buried in the trench 8 via the gate insulating film 9. A trench-gate insulated gate electrode structure (9, 10) is constituted by the gate insulating film 9 and the gate electrode 10. Note that, in the drawing, the top surface of the gate electrode 10 is located at the same depth position as the top surface of the source region 6, but the top surface of the gate electrode 10 may be slightly recessed to be located at a position deeper than the top surface of the source region 6.

The gate insulating film 9 may be a single layer film composed of any one of a silicon oxide film (SiO₂ film), a silicon oxynitride (SiON) film, a strontium oxide (SrO) film, a silicon nitride (Si₃N₄) film, an aluminum oxide (Al₂O₃) film, a magnesium oxide (MgO) film, a yttrium oxide (Y₂O₃) film, a hafnium oxide (HfO₂) film, a zirconium oxide (ZrO₂) film, a tantalum oxide (Ta₂O₅) film, and a bismuth oxide (Bi₂O₃) film, or a composite film formed by stacking some of these films. The material usable for the gate electrode 10 may be, for example, a polysilicon layer (a doped polysilicon layer) doped with p-type impurities or n-type impurities at a high impurity concentration, or high melting point metals such as titanium (Ti), tungsten (W), or nickel (Ni). The gate insulating film 9 has a thickness of approximately 30 nm or more and 100 nm or less, for example.

A gate bottom protection region 4 of the second conductivity type (p⁺-type) is provided within the current spreading layer 3 and at the bottom of the trench 8. The top surface of the gate bottom protection region 4 is in contact with the bottom surface of the trench 8. The gate bottom protection region 4 has an impurity concentration of approximately 1 × 10¹⁷ cm⁻³ or more and 1 × 10¹⁹ cm⁻³ or less.

The unit cells C1, C2, C3 illustrated in FIG. 2 have similar configurations. Accordingly, the configuration of the unit cell with the FinFET structure will be further described with reference to FIG. 3 by taking the unit cell C2 as an example. The trench 8, the gate insulating film 9, and the gate electrode 10 located on the left side of the Fin section 15 of the unit cell C2 on the surface of paper may be referred to as a trench 8L, a gate insulating film 9L, and a gate electrode 10L. The trench 8, the gate insulating film 9, and the gate electrode 10 located on the right side of the Fin section 15 of the unit cell C2 on the surface of paper may be referred to as a trench 8R, a gate insulating film 9R, and a gate electrode 10R.

The Fin section 15 has a width w1, which is a distance between the trench 8L and the trench 8R, namely, the first interval. In addition, the width w1 of the Fin section 15 corresponds to the widths of the base region 5, the source region 6, and the current spreading layer 3 located between the trench 8L and the trench 8R. The width w1 of the Fin section 15 is approximately 0.3 μm or less, for example. More preferably, the width w1 of the Fin section 15 is approximately 50 nm or more and 0.2 μm or less, for example. The width w1 of the Fin section 15 may be approximately 0.1 μm or more and 0.2 μm or less, and may be approximately 50 nm or more and 0.1 μm or less. One feature of the FinFET is that the width w1 is small as described above.

The following describes the operation of a normal FET with a sufficiently large width w1 and the operation of the FinFET illustrated in FIG. 3. First, a gate voltage equal to or more than a threshold is applied to the gate electrodes 10L, 10R. In the case of the normal FET, when the gate voltage equal to or more than the threshold is applied to the gate electrode 10, an inversion layer CH is formed along the interface between the base region 5 and the gate insulating film 9. In contrast, in the case of the FinFET illustrated in FIG. 3, the width w1 of the Fin section 15 is sufficiently small, so that voltages from the gate electrodes 10L, 10R are applied to the whole base region 5. As a result, in the base region 5, the inversion layer CH is formed in a region (a bulk region) separated from the interfaces between the base region 5 and the gate insulating films 9L, 9R. For example, the inversion layer CH is formed at a position separated from the interface by approximately 0.05 μm or more and 0.1 μm or less. Also, the inversion layer CH is formed in a central portion of the base region 5 in the right-left direction on the surface of paper, for example. Accordingly, in comparison with the normal FET, in the case of the FinFET, electrons moving in the inversion layer CH are less susceptible to the interface state densities of the interfaces between the base region 5 and the gate insulating films 9L, 9R. As a result, electronic mobility can be raised, and conduction resistance (ON resistance) can be suppressed. Here, SiC is a compound, and the interface state density of SiC in the oxide film is approximately one order of magnitude higher than that of Si. Accordingly, the electron mobility of a gate type semiconductor device formed with SiC is more susceptible to interface state density than a gate type semiconductor device formed with Si. In view of this, the application of the FinFET structure to the gate type semiconductor device formed with SiC provides a solution to the issue of interface state density.

As described above, by adopting the FinFET structure, the conduction resistance in the base region 5 can be suppressed. However, due to the adoption of the FinFET structure, the electron transport path is narrowed in the X-direction in the semiconductor region of the Fin section 15 other than the base region 5, which makes it difficult to control the conduction resistance. In the FinFET structure of a gate semiconductor device according to a comparative example, which does not include the current spreading layer 3a, the bottom surface of the base region 5 is in direct contact with the top surface of the drift layer 2.

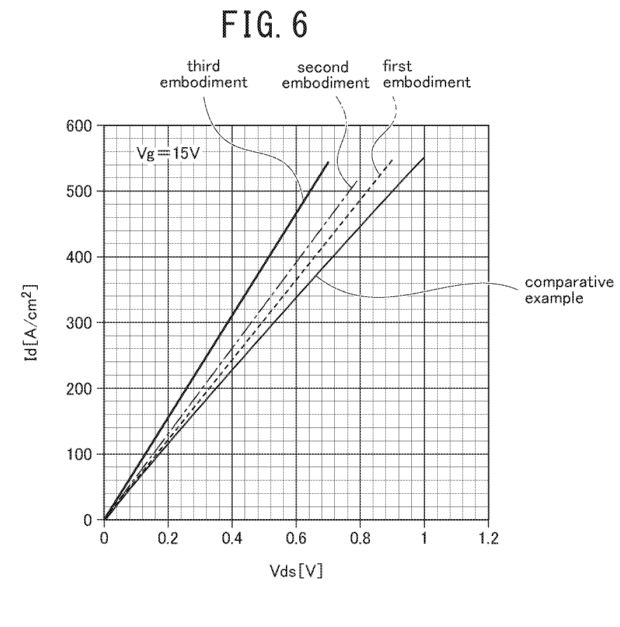

In the meantime, in the insulated gate semiconductor device according to the first embodiment, the current spreading layer 3a is present between the base region 5 and the drift layer 2. Accordingly, even when the electron transport path is narrowed along the X-direction due to the adoption of the FinFET structure, electrons are diffused downward by the current spreading layer 3a, thereby making it possible to suppress the conduction resistance. FIG. 6 illustrates simulation results of drain current density Id (A/cm²) for the insulated gate semiconductor device according to each embodiment of this disclosure and the insulated gate semiconductor device according to the comparative example. The horizontal axis in FIG. 6 represents drain-to-source voltage Vds (V), and the vertical axis represents drain current density Id (A/cm²). As illustrated in FIG. 6, in the first embodiment, the gradient of the drain current density Id with respect to the drain-to-source voltage Vds is larger than that in the comparative example, and the drain current density Id is larger than that in the comparative example. It is found that conduction resistance is suppressed more (lower) in the first embodiment than in the comparative example.

As illustrated in FIG. 2, an interlayer insulating film 11 is provided on the top surface side of the gate electrode 10. The interlayer insulating film 11 covers the gate electrode 10. The interlayer insulating film 11 may be, for example, a single layer film such as a silicon oxide film (BPSG film) to which boron (B) and phosphor (P) are added, a silicon oxide film (PSG film) to which phosphor (P) is added, an undoped silicon oxide film called "NSG," which does not contain phosphor (P) and boron (B), a silicon oxide film (BSG film) to which boron (B) is added, and a silicon nitride film (Si₃N₄ film), or a stacked-layer film obtained by stacking some of them. The interlayer insulating film 11 has an opening 11a that exposes the top surfaces of the source region 6 and the base contact region 7. Although not illustrated herein, the surface of the interlayer insulating film may be covered with a barrier metal film made of titanium, titanium nitride, or the like.

A contact electrode 12 is buried in the opening 11a. The bottom surface of the contact electrode 12 is in contact with the top surfaces of the source region 6 and the base contact region 7. The contact electrode 12 includes a lower layer 12a directly in contact with the top surfaces of the source region 6 and the base contact region 7, and an upper layer 12b contact with the top surface of the lower layer 12a. The lower layer 12a is a known ohmic metal layer and is made of nickel (Ni) or a material containing nickel and silicide, for example. The lower layer 12a may be a single layer film or may be a stacked-layer film stacked of multiple types of metals. The lower layer 12a is in low resistance ohmic contact with the source region 6 and the base contact region 7. The upper layer 12b is made of a conductive material such as metal, for example, tungsten (W).

A first main electrode (source electrode) 13 is provided to cover the top surfaces of the interlayer insulating film 11 and the contact electrode 12. The source electrode 13 is in contact with the contact electrode 12 such that they are electrically connected to each other. The source electrode 13 is made of a metal such as aluminum (Al), aluminum-silicon (Al-Si), aluminum-silicon-copper (Al-Si-Cu), or aluminum-copper (Al-Cu), for example. Since the interlayer insulating film 11 is exposed between the contact electrodes 12, the adhesion between the source electrode 13 and the underlying layer can be enhanced.

A second main electrode region (drain region) 1 of the first conductivity type (n⁺-type) with a higher impurity concentration than that of the drift layer 2 is provided on the bottom surface side of the drift layer 2. The drain region 1 is constituted by a semiconductor substrate (SiC substrate) made of SiC, for example. The drain region 1 has an impurity concentration of approximately 1 × 10¹⁹ cm⁻³ or more and 3 × 10²⁰ cm⁻³ or less, for example. The drain region 1 has a thickness of approximately 30 μm or more and 500 μm or less, for example. Note that a dislocation conversion layer or a recombination promotion layer, which is an n-type buffer layer with an impurity concentration higher than that of the drift layer 2 and lower than that of the drain region 1, may be provided between the drift layer 2 and the drain region 1.

A second main electrode (drain electrode) 14 is provided on the bottom surface side of the drain region 1. The drain electrode 14 may be a single layer film made of gold (Au), for example, or a metal film formed by stacking titanium (Ti), nickel (Ni), and Au in this order from the drain region 1 side, and a metal film made of molybdenum (Mo), tungsten (W), or the like may be further stacked as the lowest layer under the drain electrode 14. A drain contact layer such as a nickel silicide (NiSiₓ) film for an ohmic contact may be provided between the drain region 1 and the drain electrode 14. Note that, in the present specification, the expression "main electrode" alone shall be understood to denote the appropriate one of the first main electrode and the second main electrode based on a common general technical knowledge of those skilled in the art.

At the time of operating the insulated gate semiconductor device according to the first embodiment, a positive voltage is applied to the drain electrode 14 with the source electrode 13 at ground potential. When a positive voltage equal to or more than a threshold is applied to the gate electrodes 10 in that state, an inversion layer (channel) CH is formed in a region of the base region 5 which region is separated from the interface between the base region 5 and the trench 8 to establish an ON state, as illustrated in FIG. 3. In the ON state, current flows from the drain electrode 14 to the source electrode 13 via the drain region 1, the drift layer 2, the current spreading layer 3, the inversion layer CH of the base region 5, the source region 6, and the contact electrode 12. In the meantime, in the case where the voltage applied to the gate electrodes 10 is less than the threshold, no inversion layer CH is formed in the base region 5, so that the insulated gate semiconductor device enters an OFF state, and no current flows from the drain electrode 14 to the source electrode 13.

### Main Effect of First Embodiment

In the insulated gate semiconductor device according to the first embodiment, the current spreading layer 3a having a higher impurity concentration than the drift layer 2 is located between two trenches 8 adjacent to each other. Accordingly, even when the FinFET structure is adopted, electrons are diffused downward by the current spreading layer 3a, thereby making it possible to suppress conduction resistance.

### SECOND EMBODIMENT

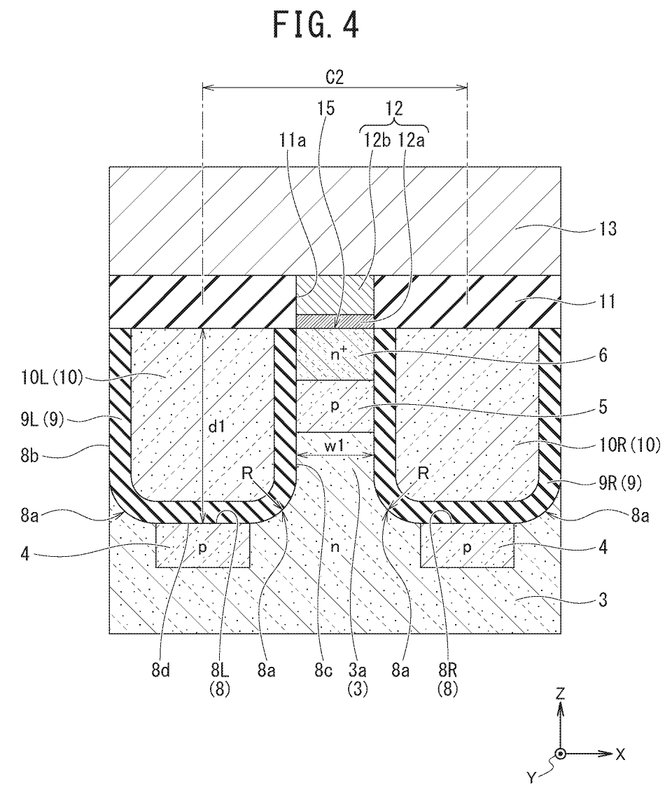

An insulated gate semiconductor device according to a second embodiment is different from the insulated gate semiconductor device according to the first embodiment illustrated in FIG. 3 in that the trench 8 has a lower corner 8a having a curvature radius R as illustrated in FIG. 4. The same constituent components described above have the same reference signs as in the first embodiment and are not described herein. The insulated gate semiconductor device according to the second embodiment also includes the current spreading layers 3, 3a, similarly to the insulated gate semiconductor device according to the first embodiment.

As illustrated in FIG. 4, each trench 8 includes a side wall 8b and a side wall 8c facing each other along the arrangement direction (the X-direction) of the trenches 8, and a bottom surface 8d. The lower corner 8a of the trench 8 is a portion in which the bottom surface 8d is in contact with the side wall 8b, or a portion in which the bottom surface 8d is in contact with the side wall 8c. It is desirable that the corner 8a be chamfered and have a curved surface the curvature radius R of which is approximately 0.1 μm or more. The curvature radius R is preferably approximately 0.1 μm or more and 0.25 μm or less, and the maximum of the curvature radius R may be approximately half of the width w1 (FIG. 3) of the trench 8 in the arrangement direction. Since the corner 8a has the curved surface with the above curvature radius R, the semiconductor region near the lower end of the Fin section 15 expands along the X-direction. This causes the electron transport path to expand along the X-direction.

Besides, since the corner 8a has the curved surface, the electric field is less likely to concentrate at the corner 8a. In view of this, the dimension of the gate bottom protection region 4 along the X-direction may be reduced. For example, the dimension of the gate bottom protection region 4 in the X-direction may be smaller than the dimension of the trench 8 in the X-direction. In the X-direction, an end portion of the gate bottom protection region 4 which end portion is on one side (the left side on the surface of paper) is located nearer to the center of the trench 8 in the X-direction than the side wall 8b, and an end portion of the gate bottom protection region 4 which end portion is on the other side (the right side on the surface of paper) is located nearer to the center of the trench 8 in the X-direction than the side wall 8c. Note that the gate bottom protection region 4 may be in contact with only a linear portion of the bottom surface 8d of the trench 8, as illustrated in FIG. 4. With such a configuration of the gate bottom protection region 4, the distance between gate bottom protection regions 4 increases, so that the current spreading layer 3 located between the gate bottom protection region 4 expands along the X-direction. This causes the electron transport path to expand along the X-direction. Also, since the distance between the gate bottom protection regions 4 increases, the influence of JFET resistance can be suppressed. As illustrated in FIG. 6, in the second embodiment, the gradient of the drain current density Id with respect to the drain-to-source voltage Vds is larger than those in the comparative example and the first embodiment, and the drain current density Id is larger than those in the comparative example and the first embodiment. It is found that conduction resistance is suppressed more (lower) in the second embodiment than in the comparative example and the first embodiment.

Note that, in a case where the corner 8a is chamfered only for the purpose of suppressing the electric field concentration at the corner 8a, the curvature radius R of the corner 8a should be approximately 0.05 μm. However, in the case where the curvature radius R of the corner 8a is approximately 0.05 μm, it is difficult to obtain the effect of suppressing conduction resistance.

### Main Effect of Second Embodiment

The outline of the second embodiment will be described before main effects of the second embodiment are described. In the insulated gate semiconductor device according to the comparative example in which the corner 8a is not chamfered, electrons are likely to be affected by JFET resistance in the vicinity of the lower end of the Fin section 15. More specifically, since the p-type gate bottom protection regions 4 face each other in the lateral direction across the n-type current spreading layer 3 having the width w1, electrons right after passing through the Fin section 15 from top to bottom are likely to be affected by JFET resistance. Similarly, in the insulated gate semiconductor device according to the comparative example which just aims for suppressing the electric field concentration at the corner 8a and in which the curved surface of the corner 8a does not have a sufficiently large curvature radius, electrons are likely to be affected by JFET resistance in the vicinity of the lower end of the Fin section 15.

In contrast, in the insulated gate semiconductor device according to the second embodiment of this disclosure, the corner 8a has a curved surface the curvature radius R of which is 0.1 μm or more and 0.25 μm or less. Since the curvature radius R of the curved surface of the corner 8a is large, it is possible to suppress the electron transport path from being narrowed along the X-direction. In addition, in the insulated gate semiconductor device according to the second embodiment of this disclosure, the corner 8a has a curved surface the curvature radius R of which is 0.1 μm or more and 0.25 μm or less, so that the electric field strength of the lower end portion of the trench 8 is decreased, thereby making it possible to suppress dV/dt at the time when the transistor turns off.

In the insulated gate semiconductor device according to the second embodiment, one end portion and the other end portion of the gate bottom protection region 4 in the X-direction are located nearer to the center of the trench 8 than the pair of side walls 8b, 8c of the trench 8. Since the width of the current spreading layer 3 sandwiched between the gate bottom protection region 4 adjacent to each other is widened, it is possible to suppress the electron transport path from being narrowed along the X-direction. Besides, the influence of JFET resistance can be suppressed.

### THIRD EMBODIMENT

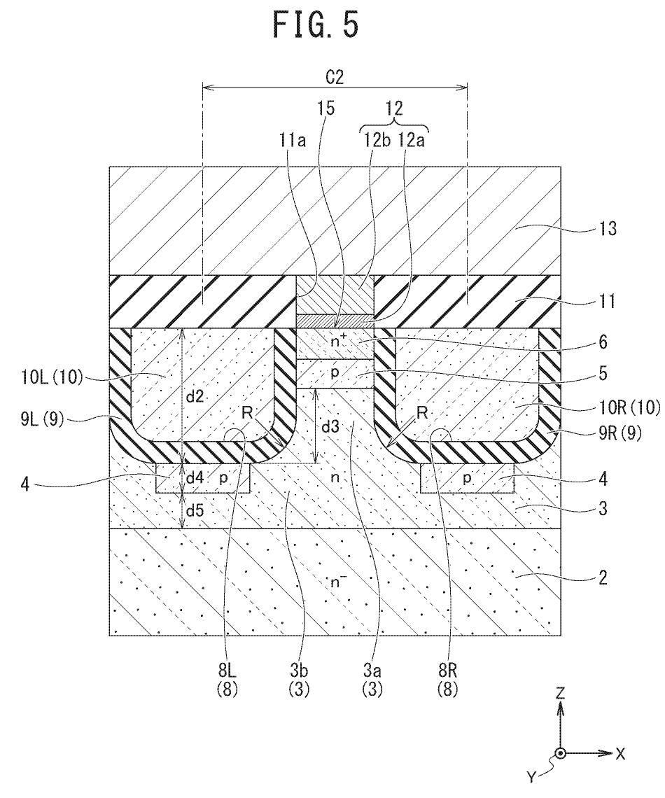

An insulated gate semiconductor device according to a third embodiment is different from the insulated gate semiconductor device according to the second embodiment illustrated in FIG. 4 in the depth of the trench 8 as illustrated in FIG. 5. The same constituent components described above have the same reference signs as in the first and second embodiments and are not described herein. The insulated gate semiconductor device according to the third embodiment also includes the current spreading layers 3, 3a, similarly to the insulated gate semiconductor devices according to the first and second embodiments. The corner 8a in the insulated gate semiconductor device according to the third embodiment has the same curvature radius R as the corner 8a in the insulated gate semiconductor device according to the second embodiment. The Fin section 15 of the present embodiment has the width w1, which is the same as the width of the Fin section 15 in the first and the second embodiments, but the width w1 is not illustrated in FIG. 5.

In the present embodiment, the depth dimension of the trench 8 is reduced relative to the depth dimension of the trench 8 in the first and the second embodiments. The depth dimension d1 of the trench 8 in the first and the second embodiments illustrated in FIGS. 3 and 4 is approximately 1 μm, for example. The trench 8 in the present embodiment, illustrated in FIG. 5, has a depth dimension d2, which is approximately half of the depth dimension d1, for example. The depth dimension d2 is preferably about 0.3 μm or more and 0.6 μm or less. By reducing the depth dimension of the trench 8, the electron transport path along the depth direction is shortened. For example, by reducing the depth dimension, it is possible to reduce a depth dimension d3 of the current spreading layer 3a located between the trenches 8 adjacent to each other. This makes it possible to suppress conduction resistance. The depth dimension d3 is approximately 0.2 μm or more and 0.4 μm or less, for example.

In the present embodiment, the dimension of a bottom-side portion of the current spreading layer 3 is reduced relative to the depth dimension of the current spreading layer 3 in the first and the second embodiments. That is, the overall depth dimension of the current spreading layer 3 is reduced in the present embodiment. The bottom-side portion of the current spreading layer 3 is a portion of the current spreading layer 3 below the bottom surface of the trench 8 and is referred to as a current spreading layer 3b to be distinguished from the current spreading layer 3a. In a case where the current spreading layers 3a, 3b are not distinguished from each other, they are just referred to as the current spreading layer 3. The depth dimension of the current spreading layer 3b corresponds to the total dimension of a depth dimension d4 of the gate bottom protection region 4 and a distance d5 from the bottom surface of the gate bottom protection region 4 to the bottom surface of the current spreading layer 3, for example.

In the present embodiment, the depth dimension d4 of the gate bottom protection region 4 is reduced relative to the depth dimension of the gate bottom protection region 4 in the first and the second embodiments. The depth dimension d4 is approximately 0.1 μm or more and 0.2 μm or less, for example. By reducing the depth dimension d4, it is possible to reduce the depth dimension of the current spreading layer 3a located between the gate bottom protection regions 4 adjacent to each other, so that the electron transport path along the depth direction is shortened. By reducing the depth dimension of the current spreading layer 3a, the influence of JFET resistance can be suppressed. Note that, when the depth dimension d4 of the gate bottom protection region 4 is approximately 0.1 μm, it is possible to obtain the effect of suppressing the electric field concentration at the bottom surface of the trench 8.

In the present embodiment, the distance d5 from the bottom surface of the gate bottom protection region 4 to the bottom surface of the current spreading layer 3 is reduced. The distance d5 is approximately 0.1 μm or more and 0.2 μm or less, for example. The electron transport path along the depth direction is shortened by reducing the distance d5. In addition, the influence of JFET resistance can be suppressed by reducing the distance d5.

In the present embodiment, the depth dimensions of the source region 6 and the base region 5 may be also reduced as the depth dimension of the trench 8 is reduced. The depth dimension of the source region 6 may be approximately 0.2 μm or less, for example. The depth dimension of the base region 5 may be approximately 0.25 μm or less, for example.

As illustrated in FIG. 6, in the third embodiment, the gradient of the drain current density Id with respect to the drain-to-source voltage Vds is larger than those in the comparative example, the first embodiment, and the second embodiment, and the drain current density Id is larger than those in the comparative example, the first embodiment, and the second embodiment. It is found that conduction resistance is suppressed more (lower) in the third embodiment than in the comparative example, the first embodiment, and the second embodiment.

### Main Effect of Third Embodiment

In the insulated gate semiconductor device according to the third embodiment of this disclosure, since the depth dimension of the trench is reduced to approximately 0.3 μm or more and 0.6 μm or less, the depth dimension d3 of the current spreading layer 3a can be reduced. Hereby, even when the current spreading layer 3a is narrowed along the X-direction due to the adoption of the FinFET structure, the electron transport path along the depth direction is reduced, so that conduction resistance can be suppressed.

In the insulated gate semiconductor device according to the third embodiment of this disclosure, since the depth dimension d4 of the gate bottom protection region 4 is reduced to approximately 0.1 μm or more and 0.2 μm or less, the depth dimension of the current spreading layer 3a located between the gate bottom protection regions 4 adjacent to each other can be reduced. Hereby, conduction resistance can be suppressed, and the influence of JFET resistance can be suppressed.

In the insulated gate semiconductor device according to the third embodiment of this disclosure, the distance d5 from the bottom surface of the gate bottom protection region to the bottom surface of the current spreading layer is reduced to approximately 0.1 μm or more and 0.2 μm or less. Hereby, conduction resistance can be suppressed, and the influence of JFET resistance can be suppressed.

Note that, generally, as dV/dt increases at the time when the transistor turns off, the transistor may tend to be broken. Generally, ion implantation of aluminum (Al) is performed to form a p-type SiC semiconductor region. However, the resistance of aluminum increases when the temperature is about -20°C or lower. When the resistance of aluminum increases due to the temperature decrease, dV/dt increases. In the present embodiment, since conduction resistance can be restrained by the above configuration, even when the resistance of aluminum increases due to the temperature decrease, a decrease in reliability can be suppressed. For example, the dV/dt tolerance at -55°C can be improved.

### OTHER EMBODIMENTS

The first to third embodiments of this disclosure has been described above, but it should not be understood that the description and the drawings as part of this disclosure restrict this disclosure. Various alternative embodiments, examples, and operational technologies will become clear to a person skilled in the art from this disclosure.

For example, the FET is described as an example of the semiconductor devices according to the first to third embodiments. However, the present invention is also applicable to an insulated gate bipolar transistor (IGBT) configured such that a p⁺-type collector region is provided instead of the n⁺-type drain region 1. Other than a single IGBT, the present invention is also applicable to a reverse conductive IGBT (RC- IGBT) or a reverse blocking insulated gate bipolar transistor (RB-IGBT).

The configurations disclosed in the first to third embodiments can be combined appropriately as far as no consistency occurs. It is needless to say that this disclosure includes various embodiments and so on that are not described herein. Accordingly, the technical scope of this disclosure is determined only by the invention specification matter according to appropriate claims from the above description.

Since conduction resistance can be suppressed in the first embodiment and the second embodiment, even when the resistance of aluminum increases due to the temperature decrease, a decrease in reliability can be suppressed. For example, the dV/dt tolerance at -55°C can be improved.

1. An insulated gate semiconductor device, comprising:
a drift layer of a first conductivity type;
a current spreading layer of the first conductivity type, provided on a top surface side of the drift layer and having a higher impurity concentration than the drift layer;
a base region of a second conductivity type, provided on a top surface side of the current spreading layer;
a main electrode region of the first conductivity type, provided on a top surface side of the base region;
a plurality of trenches extending through the main electrode region and the base region and arranged at a first interval in a plan view; and
a gate electrode buried in each of the plurality of trenches via a gate insulating film and configured to form an inversion layer in a region of the base region which region is separated from an interface between the base region and the each of the plurality of trenches in response to voltage application, wherein
the current spreading layer includes a top-side portion located between two adjacent trenches among the plurality of trenches.

2. The insulated gate semiconductor device according to claim 1, further comprising:
a gate bottom protection region of the second conductivity type, provided in the current spreading layer and in contact with a bottom surface of the trench for each of the plurality of trenches.

3. The insulated gate semiconductor device according to claim 1, wherein
each of the plurality of trenches has a depth dimension of 0.3 μm or more and 0.6 μm or less.

4. The insulated gate semiconductor device according to claim 3, further comprising:
a gate bottom protection region of the second conductivity type, provided in the current spreading layer and in contact with a bottom surface of the trench for each of the plurality of trenches,
wherein
the gate bottom protection region has a depth dimension of 0.1 μm or more and 0.2 μm or less.

5. The insulated gate semiconductor device according to claim 4, wherein
the gate bottom protection region has a bottom surface separated from a bottom surface of the current spreading layer by 0.1 μm or more and 0.2 μm or less.

6. The insulated gate semiconductor device according to claim 1, wherein
each of the plurality of trenches includes a lower corner having a curved surface with a curvature radius of 0.1 μm or more and 0.25 μm or less.

7. The insulated gate semiconductor device according to claim 1, wherein:
each of the plurality of trenches includes a lower corner having a curved surface with a curvature radius of 0.1 μm or more and 0.25 μm or less;
the insulated gate semiconductor device further comprises a gate bottom protection region of the second conductivity type, provided in the current spreading layer and in contact with a bottom surface of the trench for each of the plurality of trenches; and
one end portion and the other end portion of the gate bottom protection region in an arrangement direction the plurality of trenches are located nearer to a center of the trench than a pair of side walls of the trench.

8. The insulated gate semiconductor device according to claim 1, wherein
the first interval is 0.3 μm or less.

9. The insulated gate semiconductor device according to claim 1, wherein
the drift layer, the base region, and the main electrode region are made of silicon carbide or silicon.
